(19) United States
(12) Patent Application Publication
(10) Pub. No.: US 2024/0292638 A1
(43) Pub. Date: Aug. 29, 2024

(54) SEMI-TRANSPARENT ORGANIC OPTOELECTRONIC DEVICE

(71) Applicants: Universal Display Corporation, Ewing, NJ (US); The Regents of the University of Michigan, Ann Arbor, MI (US)

(72) Inventors: Michael Hack, Carmel, CA (US); Stephen R. Forrest, Ann Arbor, MI (US)

(21) Appl. No.: 18/590,297

(22) Filed: Feb. 28, 2024

Related U.S. Application Data
(60) Provisional application No. 63/487,382, filed on Feb. 28, 2023.

(51) Int. Cl. H10K 30/50; H02S 20/10; H02S 30/20; H10K 30/10; H10K 30/87; H10K 39/10

(52) U.S. Cl. CPC H10K 30/50; H10K 30/87; H10K 39/10; H02S 20/10; H02S 30/20; H10K 30/10

(57) ABSTRACT

A transparent organic photovoltaic cell comprises first and second electrodes, and an active layer between the electrodes, comprising a combination of donor and acceptor molecules which are configured absorb light in one or more sub-spectral ranges within a total spectral range of 400 nm to 2000 nm, wherein the photovoltaic cell is configured to be placed in optical communication with a plants such that at least a portion of light not absorbed by the photovoltaic cells is transmitted to the plant.

### CROSS-REFERENCE TO RELATED APPLICATIONS

This application claims priority to U.S. provisional application No. 63/487,382 filed on Feb. 28, 2023, incorporated herein by reference in its entirety.

### STATEMENT REGARDING FEDERALLY SPONSORED RESEARCH OR DEVELOPMENT

This invention was made with government support under DE-EE0008561 awarded by the U.S. Department of Energy. The government has certain rights in the invention.

### BACKGROUND OF THE INVENTION

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

Photosensitive optoelectronic devices convert electromagnetic radiation into electricity. Solar cells, also called photovoltaic (PV) devices or cells, are a type of photosensitive optoelectronic device that is specifically used to generate electrical power. PV devices, which may generate electrical energy from light sources other than sunlight, may be used to drive power consuming loads to provide, for example, lighting, heating, or to power electronic circuitry or devices such as calculators, radios, computers or remote monitoring or communications equipment. These power generation applications may involve the charging of batteries or other energy storage devices so that operation may continue when direct illumination from the sun or other light sources is not available, or to balance the power output of the PV device with the specific applications requirements.

Traditionally, photosensitive optoelectronic devices have been constructed of a number of inorganic semiconductors, e.g., crystalline, polycrystalline and amorphous silicon, gallium arsenide, cadmium telluride, and others.

More recent efforts have focused on the use of organic photovoltaic (OPV) cells to achieve acceptable photovoltaic conversion efficiencies with economical production costs. OPVs offer a low-cost, light-weight, and mechanically flexible route to solar energy conversion. Compared with polymers, small molecule OPVs share the advantage of using materials with well-defined molecular structures and weights. This leads to a reliable pathway for purification and the ability to deposit multiple layers using highly controlled thermal deposition without concern for dissolving, and thus damaging, previously deposited layers or sub-cells.

In addition to the pursuit of high device efficiency, OPVs have unique advantages, such as the application of semi-transparent solar cells for use in building integrated photovoltaics (BIPV). Considering the vast surface areas of windows and facades in modern urban environments, developing semi-transparent solar cells with both high efficiency and transmittance has become increasingly important.

Semi-transparent Organic Photovoltaics (ST-OPVs) have been demonstrated which have visible transparencies of 50%, along with power conversion efficiencies of 10%. The transparencies can in some embodiments be tuned from 0-100%, with efficiencies as high as 20% (depending on the transparency). Further, previous work has demonstrated operational lifetimes>>30 years. ST solar cells have been proposed and demonstrated for use in greenhouses since they can allow visible radiation to nourish the plants while providing electricity, thus in principle allowing for carbon-negative greenhouse operation.

However, there is a much larger application space for ST-OPVs. That is outdoors in fields. Today, Germany has limited the deployment of solar panels on farmland to 20% of a farmer's acreage since farmers have found that serving as solar power stations is more lucrative than growing crops or grazing livestock. This is an unnecessary trade-off. Thus, there is a need in the art for an outdoor OPV architecture which allows for simultaneous power generation and agriculture.

### SUMMARY OF THE INVENTION

Some embodiments of the invention disclosed herein are set forth below, and any combination of these embodiments (or portions thereof) may be made to define another embodiment.

In one aspect, a transparent organic photovoltaic cell comprises first and second electrodes and an active layer between the electrodes, comprising a combination of donor and acceptor molecules which are configured absorb light in one or more sub-spectral ranges within a total spectral range of 400 nm to 2000 nm.

In one embodiment, the photovoltaic cell is configured to be placed in optical communication with a plant such that at least a portion of light not absorbed by the photovoltaic cell is transmitted to the plant.

In one embodiment, the photovoltaic cell is configured to absorb more energy in the wavelength range from 750 nm to 2.0 μm than in the range from 400 nm to 750 nm.

In one embodiment, the photovoltaic cell is configured to absorb more energy in the wavelength range from 700 nm to 1.2 μm than in the range from 400 nm to 700 nm.

In one embodiment, the photovoltaic cell is configured to absorb more energy in the wavelength range from 700 nm to 1.0 μm than in the range from 400 nm to 700 nm.

In one embodiment, the photovoltaic cell is configured such that the photovoltaic cell transmission is at least 30%, higher for a wavelength associated with an absorption peak of the plant than at wavelengths 100 nm on either side of the plant absorption peak.

In one embodiment, the photovoltaic cell is configured such that the photovoltaic cell transmission is at least 30%, higher at two or more wavelengths associated with two or more absorption peaks of the plant than at wavelengths 100 nm on either side of the two or more plant absorption peaks.

In one embodiment, the photovoltaic cell is configured such that the photovoltaic cell transmission is at least 30%, higher at a wavelength between two or more absorption peaks of the plant.

In one embodiment, the photovoltaic cell is configured to transmit over 50% of light within +/−50 nm of a dominant plant absorption peak.

In one embodiment, the photovoltaic cell is configured to transmit over 30% of light within +/−50 nm of a dominant plant absorption peak.

In one embodiment, the photovoltaic cell is configured such that over 50% of light in a spectral range from 400 nm to 480 nm is transmitted, while at least 30% of light outside of the spectral range is reflected back into the cell.

In one embodiment, the photovoltaic cell is configured such that over 50% of light in a spectral range from 600 nm to 700 nm is transmitted, while at least 30% of light outside of the spectral range is reflected back into the cell.

In one embodiment, the photovoltaic cell is configured such that over 50% of light in a combined spectral range of 400 nm to 480 nm and 600 nm to 700 nm is transmitted, while at least 30% of light outside of the combined spectral range is reflected back into the cell.

In one embodiment, the cell further comprises a stack comprising a plurality of optical coating layers, wherein a thickness of at least one of the optical coating layers is different than a thickness of at least one of the other optical coating layers.

In one embodiment, the photovoltaic cell is configured to absorb more energy in the wavelength range from 700 nm to 1.0 μm than in the range from 500 nm to 600 nm.

In one embodiment, the organic photovoltaic cell is configured to transmit at least 30% of light in the wavelength range from 400 nm to 750 nm.

In one embodiment, an absorption spectrum of the organic photovoltaic cell has a first absorption peak in the range of 660 nm+/−50 nm and a second absorption peak in the range of 450 nm+/−50 nm.

In one embodiment, at least 30% of the transmitted light is within ±50 nm, ±40 nm, ±30 nm, ±20 nm, or ±10 nm of the first absorption peak or the second absorption peak.

In one embodiment, the first absorption peak is centered on a wavelength in the range of 800 nm to 1000 nm.

In one embodiment, the cell further comprises two or more sub-cells, wherein each of the two or more sub-cells are configured to absorb and transmit light of different spectral wavelength ranges.

In one embodiment, absorption and transmittance characteristics of each of the two or more sub-cells is tuned based on a plant's peak photosynthetic spectrum for the plant receiving transmitted light from the corresponding sub-cell.

In another aspect, a transparent organic photovoltaic cell production method comprises depositing a first electrode onto a substrate, depositing an active layer above the first electrode, the active layer comprising a plurality of sub-layers comprising a combination of donor and acceptor molecules which are configured absorb light in one or more sub-spectral ranges within a total spectral range of 400 nm to 2000 nm, and depositing a second electrode above the active layer, wherein the photovoltaic cell is configured to be placed in optical communication with a plant such that at least a portion of light not absorbed by the photovoltaic cell is transmitted to the plant.

In one embodiment, the method further comprises the step of selecting thicknesses and materials of the plurality of sub-layers of the active layer using a transfer matrix method in combination with a genetic algorithm for optimization of light absorption for power generation and light transmission for growth of the plant in optical communication with the photovoltaic cell.

In another aspect, a transparent organic photovoltaic cell comprises first and second electrodes, and an active layer positioned between the electrodes, comprising a combination of donor and acceptor molecules configured to absorb light in specific spectral ranges including in the range of 750 nm to 990 nm, wherein the photovoltaic cell is configured to be placed in optical communication with a plant such that at least a portion of light not absorbed by the photovoltaic cell is transmitted to the plant, such that the energy absorption by the cell in the range exceeds the energy absorption by the cell in a range from 380 nm to 700 nm.

In another aspect, a solar farm comprises at least one of the transparent organic photovoltaic cells as described above, and is configured to generate electricity while providing light for plant growth below the at least one photovoltaic cell.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 shows an organic light emitting device.

FIG. 2 shows an inverted organic light emitting device that does not have a separate electron transport layer.

FIG. 3A is a schematic of an OPV encapsulated with barrier layers on both the top and bottom surfaces of the device.

FIG. 3B shows a zoomed-in view of the barrier and polymer layers comprising coating 302.

FIG. 4A is an exemplary deployment of a roll of flexible ST-OPV cells on top of a frame.

FIG. 4B is an exemplary deployment of a hinged roll of flexible ST-OPV cells on top of a frame.

FIG. 5 is an exemplary ST OPV device.

FIG. 6 is an exemplary photosynthesis spectrum.

FIG. 7 is an exemplary Photo-synthetically Active Radiation (PAR) spectrum.

FIG. 8 is an exemplary solar spectrum.

### DETAILED DESCRIPTION

It is to be understood that the figures and descriptions of the present invention have been simplified to illustrate elements that are relevant for a clear understanding of the present invention, while eliminating, for the purpose of clarity, many other elements found in related systems and methods. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Disclosed herein is a novel device architecture that enables an OPV to both produce electrical energy by harnessing wavelengths of light not utilized by growing crops, such as by harnessing infra-red light, and then allowing visible light not absorbed by the OPV device to be used for agricultural benefit.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, 6 and any whole and partial increments therebetween. This applies regardless of the breadth of the range.

As used herein, the terms “electrode” and “contact” may refer to a layer that provides a medium for delivering photo-generated current to an external circuit or providing a bias current or voltage to the device. That is, an electrode, or contact, provides the interface between the active regions of an organic photosensitive optoelectronic device and a wire, lead, trace or other means for transporting the charge carriers to or from the external circuit. Examples of electrodes include anodes and cathodes, which may be used in a photosensitive optoelectronic device.

As used herein, the term “transparent” may refer to an electrode that permits at least 50% of the incident electromagnetic radiation in relevant wavelengths to be transmitted through it. In a photosensitive optoelectronic device, it may be desirable to allow the maximum amount of ambient electromagnetic radiation from the device exterior to be admitted to the photoconductive active interior region. That is, the electromagnetic radiation must reach a photoconductive layer(s), where it can be converted to electricity by photoconductive absorption. This often dictates that at least one of the electrical contacts should be minimally absorbing and minimally reflecting of the incident electromagnetic radiation. In some cases, such a contact should be transparent or at least semi-transparent.

As used herein, the term “semi-transparent” may refer to an electrode that permits some, but less than 50% transmission of ambient electromagnetic radiation in relevant wavelengths. The opposing electrode may be a reflective material so that light which has passed through the cell without being absorbed is reflected back through the cell.

As used and depicted herein, a “layer” refers to a member or component of a photosensitive device whose primary dimension is X-Y, i.e., along its length and width. It should be understood that the term layer is not necessarily limited to single layers or sheets of materials. In addition, it should be understood that the surfaces of certain layers, including the interface(s) of such layers with other material(s) or layers(s), may be imperfect, wherein said surfaces represent an interpenetrating, entangled or convoluted network with other material(s) or layer(s). Similarly, it should also be understood that a layer may be discontinuous, such that the continuity of said layer along the X-Y dimension may be disturbed or otherwise interrupted by other layer(s) or material(s).

As used herein, a “photoactive region” refers to a region of the device that absorbs electromagnetic radiation to generate excitons. Similarly, a layer is “photoactive” if it absorbs electromagnetic radiation to generate excitons. The excitons may dissociate into an electron and a hole in order to generate an electrical current.

As used herein, the terms “donor” and “acceptor” refer to the relative positions of the highest occupied molecular orbital (“HOMO”) and lowest unoccupied molecular orbital (“LUMO”) energy levels of two contacting but different organic materials. If the LUMO energy level of one material in contact with another is lower, then that material is an acceptor. Otherwise it is a donor. It is energetically favorable, in the absence of an external bias, for electrons at a donor-acceptor junction to move into the acceptor material, and for holes to move into the donor material.

As used herein, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Because ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, the term “band gap” (E_{g}) of a polymer may refer to the energy difference between the HOMO and the LUMO. The band gap is typically reported in electronvolts (eV). The band gap may be measured from the UV-vis spectroscopy or cyclic voltammetry. A “low band gap” polymer may refer to a polymer with a band gap below 2 eV, e.g., the polymer absorbs light with wavelengths longer than 620 nm.

As used herein, the term “excitation binding energy” (E_{B}) may refer to the following formula: E_{B}=(M⁺+M⁻)−(M*+M), where M⁺ and M⁻ are the total energy of a positively and negatively charged molecule, respectively; M* and M are the molecular energy at the first singlet state (S₁) and ground state, respectively. Excitation binding energy of acceptor or donor molecules affects the energy offset needed for efficient exciton dissociation. In certain examples, the escape yield of a hole increases as the HOMO offset increases. A decrease of exciton binding energy E_{B} for the acceptor molecule leads to an increase of hole escape yield for the same HOMO offset between donor and acceptor molecules.

As used herein, power conversion efficiency (η_{ρ}) may be expressed as:

$${η}_{ρ} = \frac{{V}_{o c} * F F * {J}_{s c}}{{P}_{o}}$$

wherein V_{OC} is the open circuit voltage, FF is the fill factor, J_{SC} is the short circuit current, and P_{O} is the input optical power.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which comprises a series of chemical shells built on the core moiety. A dendrimer may be a “small molecule,” and it is believed that all dendrimers currently used in the field of organic optoelectronic devices are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of a material. A ligand may be referred to as “ancillary” when it is believed that the ligand does not contribute to the photoactive properties of a material, although an ancillary ligand may alter the properties of a photoactive ligand.

As used herein, and as would be generally understood by one skilled in the art, on a conventional energy level diagram, with the vacuum level at the top, a “shallower” energy level appears higher, or closer to the top, of such a diagram than a “deeper” energy level, which appears lower, or closer to the bottom.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution-based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material comprises essentially of polymeric silicon and inorganic silicon.

Although certain embodiments of the disclosure are discussed in relation to one particular device or type of device (for example OPVs) it is understood that the disclosed improvements may be equally applied to other devices, including but not limited to OLEDs, PLEDs, charge-coupled devices (CCDs), photosensors, or the like.

Although exemplary embodiments described herein may be presented as methods for producing particular circuits or devices, for example OPVs, it is understood that the materials and structures described herein may have applications in devices other than OPVs. For example, other optoelectronic devices such as OLEDs and organic photodetectors may employ the materials and structures. More generally, organic devices, such as organic transistors, or other organic electronic circuits or components, may employ the materials and structures.

In some embodiments, the optoelectronic device has one or more characteristics selected from the group consisting of being flexible, being rollable, being foldable, being stretchable, and being curved. In some embodiments, the optoelectronic device is transparent or semi-transparent. In some embodiments, the optoelectronic device further comprises a layer comprising carbon nanotubes.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OPV that includes the compound of the present disclosure in the organic layer in the OPV is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

According to an embodiment, the devices fabricated in accordance with embodiments of the invention may be incorporated into one or more device selected from a consumer product, an electronic component module, a lighting panel, and/or a sign or display. Further examples of such electronic products or intermediate components include solar cells, light weight solar cells, flexible solar cells, solar cells integrated with thin film electronics including for power conversion and management, thin film power supply consisting of an OPV cell integrated with thin film electronics for power consumption and management, a solar farm including one or more OPV cells and/or devices that may be integrated in an array, solar farm including semi-transparent OPV cells and/or devices for advantages related to plants/crops, an OPV, device on a same substrate as a display, such as a thin film display, with integrated or external electronics, an OPV integrated with one or more sensors, including but not limited to mechanical, electrical and/or biological sensors, an OPV on a same substrate as a radio receive/transmitter, an OPV on a same substrate as an audio producing device, an OPV on the same substrate as a computing device, an OPV for powering IT devices, an OPV for powering shelf labels, an OPV for indoor applications, an OPV for integration with a window, wall, roof, etc., an OPV for use in a solar. In an embodiment, the OPV device may be fully or partially transparent, flexible, curved, rollable, foldable, or stretchable.

According to embodiments, the devices fabricated in accordance with embodiments of the invention may be incorporated with a battery on a same substrate as the device or connected to a battery on a different substrate/device. According to embodiments, the battery may be a standard battery and/or thin film battery.

According to embodiments, the devices fabricated may be a thin film OPV device. In an embodiment, a thin film device is one where the layers of the device are deposited as opposed to being placed on the substrate.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. The hole-transporting layer can be doped by p-type conductivity dopants and n-type conductivity dopants are used in the electron-transporting layer.

For example, and without limitation, the devices described herein can be used anywhere around the world, especially countries where agriculture is present. It may be especially useful in countries, such as India, where crops provide only minimal subsistence and there is a chronic shortage of electricity; the device described solves both problems: providing food, electricity, and excess income to the farmers. The disclosed device exemplifies a truly transformative use of ST-OPVs and similar technologies that can turn farming into a carbon-neutral industry for the first time since the industrial revolution.

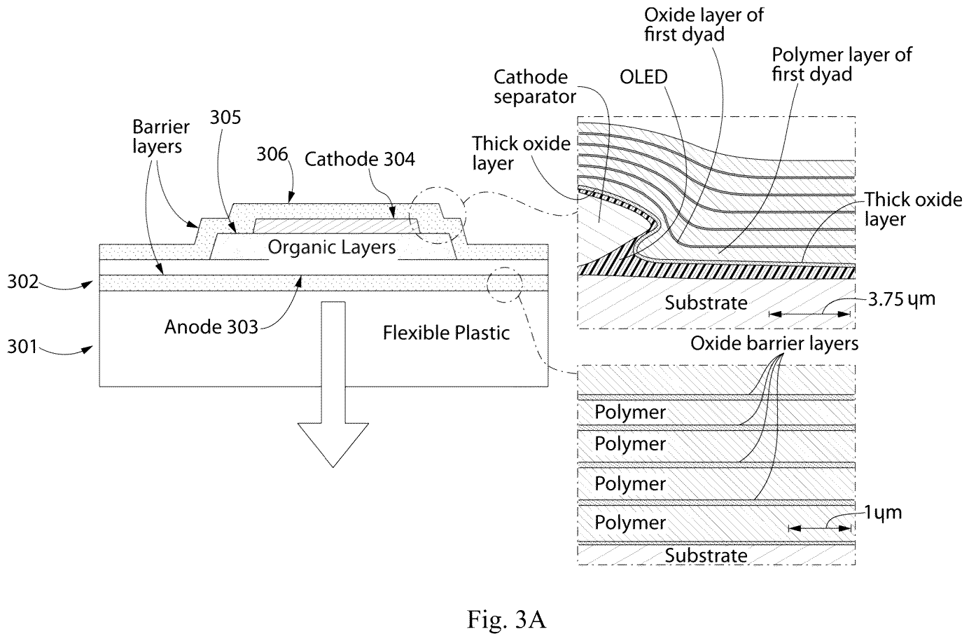

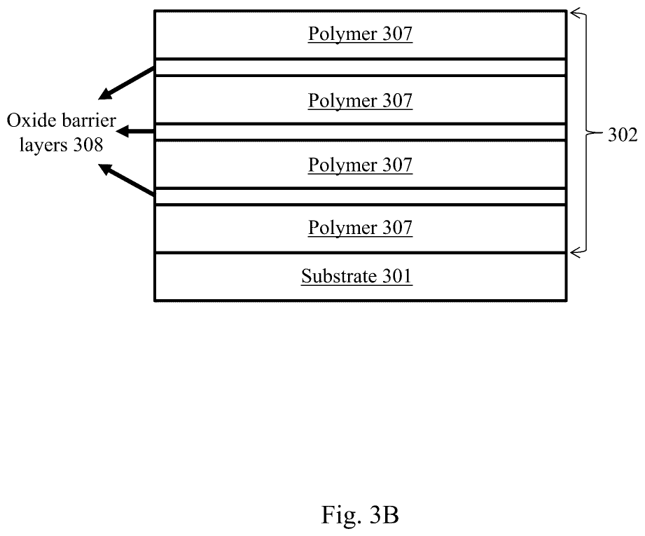

Another particular advantage of ST-OPVs, although it can be realized to a lesser extent by other thin film PV technologies, is the ability of the device to be mounted on flexible films. The devices themselves may, in some embodiments, be encapsulated against environmental degradation, for example by multilayer glass/polymer coatings as explained below and shown in FIGS. 3A-3B.

### Organic Photovoltaic Cells

Today, there is considerable competition for land use between solar power generation and agriculture. Semi-transparent organic photovoltaics can be tuned to provide maximum power generation while not impeding agriculture. In some aspects, this invention relates to improving the performance of applying semi-transparent organic solar cells over plants to both generate electricity and allow for light plant growth using the same area. It is quite wasteful to just reserve land for solar cells at the expense of agricultural potential, and vice versa. In some embodiments, by utilizing the power of organic chemistry and organic photovoltaic cells an OPV can be created in which the optical properties of the active materials can be tuned and configured to absorb light and convert into electricity in spectral ranges where the plants do not absorb and provide transparency and therefore light to growing plants where they do absorb. Thus, the properties of the OPV cells can be designed to maximize both electricity generation and light provided to plants for growth, in any given space. OPVs are suitable for this setting as no other technology can provide native transparency and generate electricity like OPVs, which allows for use of the same area for both electricity generation and plant growth. While other approaches use windows in the solar cells to provide transparency, this leads to voids in the PV where the window regions are which cannot generate electricity. Also by matching the OPV transmission/absorption to the plant absorption spectrum both plant growth and electricity generation can be maximized.

Described herein is an optoelectronic system, comprising a flexible optoelectronic device. The various systems and methods disclosed herein may be provided within a single-junction solar cell, or optoelectronic device, or a multi-junction, or tandem, solar cell. The flexible properties of the device include being rolled up for storage or being able to be placed on frames of varying shapes and sizes, as described below. The system described herein may be used by farmers as transparent solar cells over fields in order to help with plant growth and generating electricity and many other uses described herein.

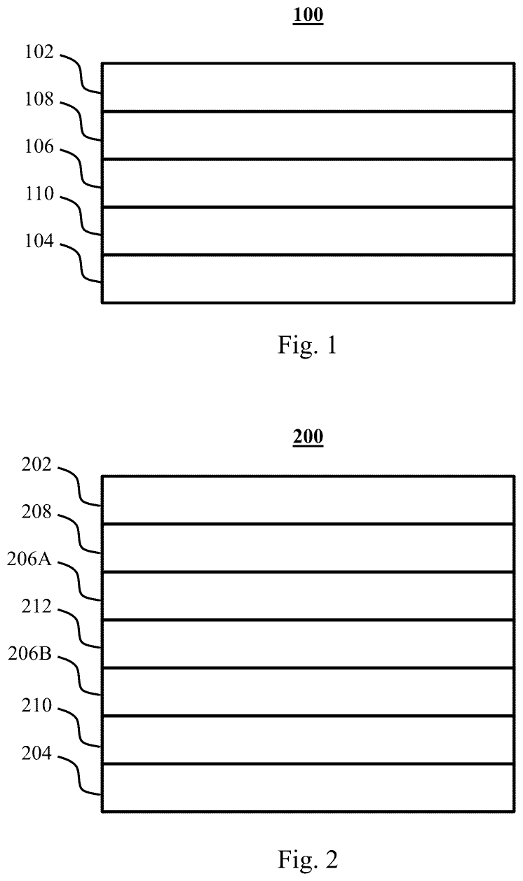

FIG. 1 depicts an example of various layers of a single-junction solar cell or organic photovoltaic cell (OPV) 100. The exemplary OPV 100 includes an anode 102, cathode 104, active layer 106, intermediate layer 108, and another intermediate layer 110.

The OPV cell may include two electrodes having an anode 102 and a cathode 104 in superposed relation, at least one donor composition, and at least one acceptor composition, wherein the donor-acceptor material or active layer 106 is positioned between the two electrodes 102, 104. In some embodiments, active layer 106 may be an organic heterojunction, as explained below. In some embodiments, at least one intermediate layer 108 may be positioned between the anode 102 and the active layer 106. Additionally, or alternatively, at least one intermediate layer 110 may be positioned between the active layer 106 and cathode 104.

Still referring to FIG. 1, the anode 102 may include a conducting oxide, thin metal layer, or conducting polymer. In some examples, the anode 102 includes a (e.g., transparent) conductive metal oxide such as indium tin oxide (ITO), tin oxide (TO), gallium indium tin oxide (GITO), zinc oxide (ZO), or zinc indium tin oxide (ZITO). In other examples, the anode 102 includes a thin metal layer, wherein the metal is selected from the group consisting of Ag, Au, Pd, Pt, Ti, V, Zn, Sn, Al, Co, Ni, Cu, Cr, or combinations thereof. In yet other examples, the anode 102 includes a (e.g., transparent) conductive polymer such as polyanaline (PANI), or 3,4-polyethylenedioxythiophene:polystyrenesulfonate (PEDOT:PSS). The thickness of the anode 102 may be 0.1-100 nm, 1-10 nm, 0.1-10 nm, or 10-100 nm.

Continuing to refer to FIG. 1, the cathode 104 may be a conducting oxide, thin metal layer, or conducting polymer similar or different from the materials discussed above for the anode 102. In certain examples, the cathode 104 may include a metal or metal alloy. The cathode 104 may include Ca, Al, Mg, Ti, W, Ag, Au, or another appropriate metal, or an alloy thereof. The thickness of the cathode 104 may be 0.1-100 nm, 1-10 nm, 0.1-10 nm, or 10-100 nm.

In some embodiments, the optoelectronic device additionally comprises a flexible plastic substrate as one of its layers. A flexible plastic substrate, as used herein, is defined as a bottom layer component of a solar cell. The substrate may protect the backside of the optoelectronic device from the effects of weather conditions and may mitigate any electric shock hazards, such as different environmental conditions like moisture, UV exposure and other performance threats. The substrate may further comprise of multiple layers of adhesives, barrier films, and/or polymers. The flexible plastic substrate may have any properties of any of the substrates described previously herein. In some embodiments, the flexible plastic substrate may be positioned under the active layer 106 or organic heterojunction. In some embodiments, the flexible plastic substrate comprises plastic, glass, or other suitable materials, such as a material that is transparent to at least a portion of the emissive spectrum of the OPV. The thickness of the flexible plastic substrate may be in the range of 10-100 μm.

In some embodiments, the optoelectronic device further comprises a coating or barrier layer over the flexible plastic substrate. The anode 102 and a cathode 104 are positioned over the coating. One purpose of the coating over the flexible plastic substrate is to protect the electrodes and organic layers of the OPV from damaging exposure to harmful species in the environment including moisture, vapor and/or gases, etc. The coating may be deposited over, under or next to a substrate, an electrode, or over any other parts of a device including an edge. The coating may comprise a single layer, or multiple layers. The coating may be formed by various known chemical vapor deposition techniques and may include compositions having a single phase as well as compositions having multiple phases. Any suitable material or combination of materials may be used for the coating. The coating may comprise a glass or a polymer. The coating may incorporate an inorganic or an organic compound or both. An exemplary coating comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material comprises of polymeric silicon and inorganic silicon. Coating is further described in reference to FIG. 3B.

As noted above, in some embodiments, the OPV may include one or more intermediate layers, for example charge collecting and transporting intermediate layers positioned between anode 102, cathode 104 and the active region or layer 106. The intermediate layer 108, 110 may be a metal oxide. In certain examples, the intermediate layer 108, 110 includes MoO₃, V₂O₅, ZₙO, or TiO₂. In some examples, the first intermediate layer 108 has a similar composition to the second intermediate layer 110. In other examples, the first and second intermediate layers 108, 110 have different compositions. The thickness of each intermediate layer may be 0.1-100 nm, 1-10 nm, 0.1-10 nm, or 10-100 nm.

In some embodiments, the active region or layer 106 positioned between the electrodes 102, 104 includes a composition or molecule having an acceptor and a donor. In an embodiment, the optoelectronic device described herein has an organic heterojunction positioned between the anode 102 and the cathode 104 among the active layer 106. The organic heterojunction has a donor, or donor material, and an acceptor, or acceptor material. In some embodiments, the composition may be arranged as an acceptor-donor-acceptor (A-D-A).

In some embodiments, the device includes an encapsulating layer positioned over the anode 102 and the cathode 104. The encapsulating layer may have any of the same properties of or be made of the same materials as the coating described above. The encapsulating layer may comprise a single layer, or multiple layers. The encapsulating layer may be formed by various known chemical vapor deposition techniques and may include compositions having a single phase as well as compositions having multiple phases. Any suitable material or combination of materials may be used for the encapsulating layer. The encapsulating layer may comprise a glass or a polymer. The encapsulating layer may incorporate an inorganic or an organic compound or both. The preferred encapsulating layer may comprise a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. In one example, the mixture of a polymeric material and a non-polymeric material comprising polymeric silicon and/or inorganic silicon.

The encapsulating layer may in some embodiments be the outermost layer of the flexible optoelectronic device and may be configured to help protect the inner layers, including the cathode and anode, from environmental or other external conditions. In an embodiment, the encapsulating layer may surround the entirety of the flexible optoelectronic device or may additionally be provided with another protective layer on top of the encapsulating layer.

Furthermore, the encapsulating layer may comprise a multilayer, wherein the multilayer comprises a plurality of molecular dyads. As used herein, the term “molecular dyads” refers to pairs of layers of different materials, for example as shown in FIG. 3A. The multilayer of the plurality of dyads may help further enhance the protection provided by the encapsulating layer. In one embodiment, the multilayer of the plurality of dyads may comprise glass, or any other similar material. The multilayer may comprise any material described in relation to the coating described previously herein. The multilayer may incorporate an inorganic or an organic compound or both. The multilayer may comprise any number of layers of dyads, for example between 2 and 10 or between 3 and 8 between 4 and 6 dyads. In one embodiment, the multilayer of dyads may include three dyads. In another embodiment, the multilayer of dyads may include two dyads. Further, each dyad of the multilayer of dyads may have a specific thickness, which in some embodiments, may be in the range of 10-500 nm or between 10 nm and 200 nm, or between 10 nm and 100 nm, or between 10 nm and 50 nm, or between 20 nm and 80 nm, or between 40 nm and 80 nm.

In some embodiments, the plurality of dyads in the multilayer may be separated by a polymer positioned between each dyad. The polymer may be any of a class of natural or synthetic substances composed of macromolecules that are multiples of monomers. The polymer may be any of the polymers as previously described herein or in referenced applications or publications. The polymer between each dyad may enable the maximum amount of light to shine through the device. Each polymer layer may have a thickness in the range of 1-10 μm.

Now referring to FIG. 2, depicted is an example of various layers of a tandem or multi-junction solar cell or organic photovoltaic cell (OPV) 200. The OPV cell may include two electrodes having an anode 202 and a cathode 204 in superposed relation, at least one donor composition, and at least one acceptor composition positioned within a plurality of active layers or regions 206A, 206B between the two electrodes 202, 204. While only two active layers or regions 206A, 206B are depicted in FIG. 2, additional active layers or regions may also be possible for the invention described herein. Anode 202 may share any of the same qualities or characteristics described above for anode 102. Cathode 204 may share any of the same qualities or characteristics described above for cathode 104. Plurality of active layers or regions 206A and 206B may share any of the same qualities or characteristics described above for active layer or region 106. At least one intermediate layer 208 may share any of the same qualities or characteristics described above for intermediate layers 108 and 110.

In one embodiment, at least one intermediate layer 208 may be positioned between the anode 202 and a first active layer 206A. Additionally, or alternatively, at least one intermediate layer 210 may be positioned between the second active layer 206B and cathode 204. Furthermore, in another embodiment, at least one intermediate layer 212 may be positioned between the first active layer 206A and the second active layer 206B. The compositions, thicknesses, etc. of each layer may be the same as those discussed with reference to FIG. 1.

In one embodiment, the plurality of active layers or regions 206A, 206B may include an organic heterojunction comprising the donor and acceptor materials. In another embodiment, the organic heterojunction may be its own organic layer or apart of any other organic layer, as long as it is positioned between the electrodes. The active region or layer 106, 206A, 206B positioned between the electrodes includes a composition or molecule having an acceptor and a donor. The composition may be arranged as an acceptor-donor-acceptor (A-D-A).

The OPV 200 may further include an encapsulating layer comprising a glass or a polymer, positioned over the anode and the cathode. The encapsulating layer may comprise of a multilayer of dyads, as explained previously. The multilayer of dyads may be separated by a polymer between each dyad.

The compositions, thicknesses, etc. of each layer may be the same as those discussed with reference to FIG. 1.

This solution could be deployed globally. Indeed, in countries such as India where crops provide only minimal subsistence, and there is a chronic shortage of electricity is an ideal location where such a solution solves both problems: providing food, electricity and excess income to the farmers. The disclosed OPVs can turn farming into a carbon neutral industry for the first time since the industrial revolution.

A particular advantage of ST-OPVs (although it can be realized to a lesser extent by other thin film PV technologies) is the ability of the modules to be mounted on flexible films. The modules themselves must be encapsulated against environmental degradation, for example by multilayer glass/polymer coatings as shown in FIGS. 3A-3B for the example of an OLED, although it is equally applicable to OPVs.

With reference to FIGS. 3A-3B, a schematic of an OPV encapsulated with barrier layers on both the top and bottom surfaces of the device on a plastic substrate is shown. Scanning electron microscope images of the flexible top and bottom multilayer encapsulation layers are at right.

Now referring to FIG. 3A, a schematic of an OPV encapsulated with barrier layers on both the top and bottom surfaces of the device on a plastic substrate is shown. As described herein, the OPV comprises a flexible plastic substrate 301, a coating 302, an anode 303, a cathode 304, an organic heterojunction 305, and an encapsulating layer 306. Scanning electron microscope images of the flexible top and bottom multilayer encapsulation layers are at right, wherein the bottom multilayer, or coating, is further shown in FIG. 3B.

The barrier layers shown may include the coating and encapsulating layers as described above. Referring now to FIG. 3B, exemplary layers of coating 302 are shown. The layers of polymers 307 are shown above flexible plastic substrate 301 that comprise the coating 302, which, in one embodiment, may have the same or similar makeup as the encapsulating layer 306. Oxide barrier layers 308 shown are synonymous with coating 302 and represent the same material doing the same function. In some embodiments, the encapsulating layer 306 may be configured to be able to be flexible enough to conform the shape of the flexible optoelectronic device; the shape of the device may depend on the varying thicknesses and shapes of the layers of the flexible device.

The devices and methods disclosed herein deploy ST-OPVs (or other transparent cell technologies) to cover large fractions and even entire fields with transparent solar cells at a height above the ground, leaving room underneath for growth or livestock. This is beneficial as the farmers can grow their crops or graze their livestock underneath, while the ST-OPVs may still allow sufficient sunlight to provide robust plant growth while simultaneously generating electricity. Thus, farmers can both generate electricity, grow their crops, and allow their livestock to graze without any solar cells getting in the way or damaged due to the environment or animals themselves.

However, an issue arises in determining how rainwater will reach the crops underneath if the transparent solar cells are covering them and inhibiting the ability to get water to the plants. In one embodiment, since the solar cells generate electricity, electric pumps may be attached to the base of the panels along with a catchment reservoir or plurality of catchment reservoirs to collect water that falls off the panels. The catchment reservoir or plurality thereof may be configured to distribute that collected water onto the ground into gutters and channels. In another embodiment, the catchment reservoirs may be connected to a sort of sprinkler or water distribution system underneath the transparent solar cells. In other embodiments, the electric pumps and catchment reservoir(s) may be located anywhere on the optoelectronic system. In another embodiment, gravity feed of water in suitably tilted landscapes can also be used to eliminate the use of pumps, such as placing the transparent solar cells on a specific angle.

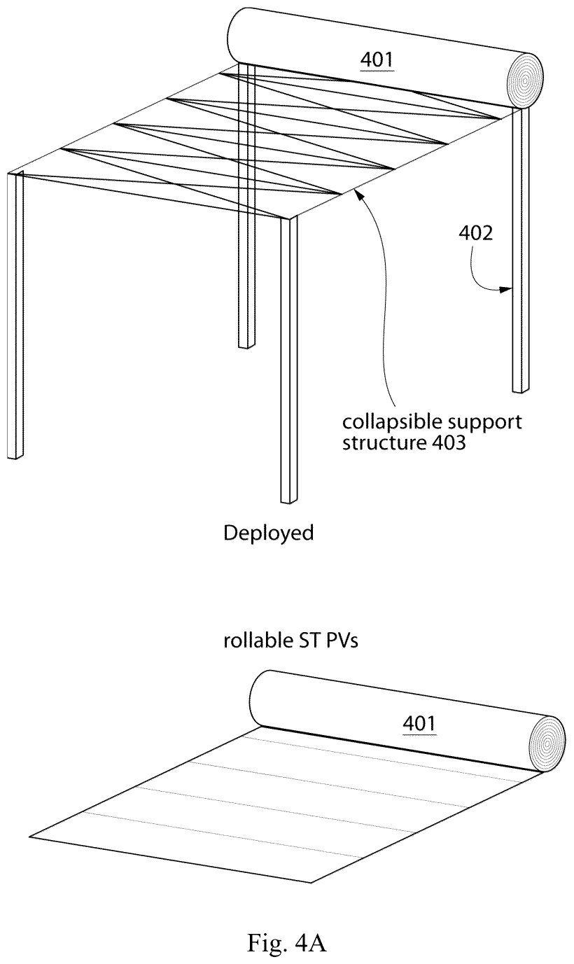

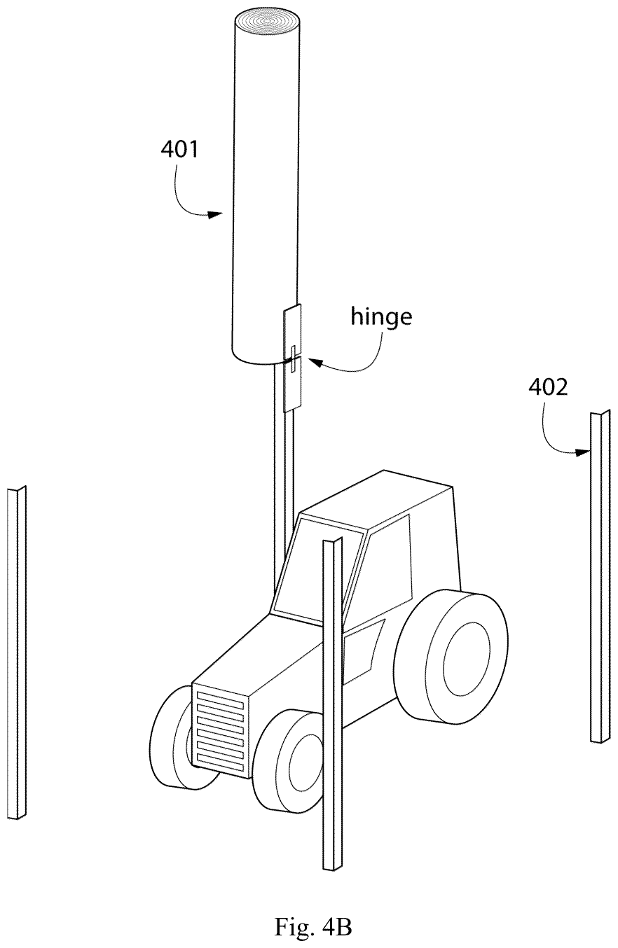

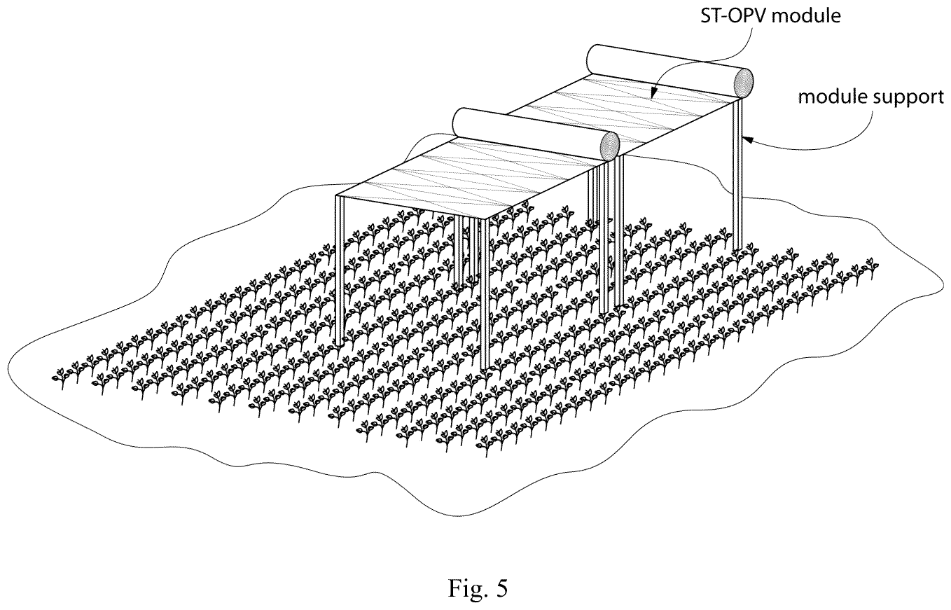

Another solution, and the one used by the invention described herein, is the transparent solar cells having the ability to be rolled up and stored away to mitigate harm from the environment and to allow rain to fall on the crops without interference. This allows the rain to fall naturally to the crops without having to be collected first and then distributed, saving time and money for the farmers. This solution is further explained below with reference to FIGS. 4A and 4B.

Now referring to FIG. 4A, the flexibility of the plastic substrate and the optoelectronic device overall allows for the transparent solar panels to be rolled up and stored away. The flexibility may allow for complete retraction of the panels. While ordinarily the panels can be mounted on supports sufficiently high such that conventional farm machinery can pass underneath, exceptionally high equipment such as combine harvesters may require unrealistically costly support systems that allow clearance. A solution to this is to retract flexible solar cells into rolls using electric motors, and a boom with a cable to hinge the roll upward and out of the way (see FIG. 4). In the deployed position, to provide the flexible films with stability, a retracting, hinged support will be required (an example of a scissor such arrangement is illustrated. The external frame, too, can be telescoping. Alternatively, the roll can just be translated upward between high supports when retracted.

Continuing to refer to FIG. 4A, roller 401 rolls the flexible optoelectronic device up in order for rain to get to the crops. Roller 401 may be initiated to roll up and store the solar cells in any way, electrically, automatically, manually, etc. The flexible optoelectronic device may further be configured to retract in the presence of rain. In an embodiment, the roller 401 may be configured to be connected to a sort of sensor or sensing device wherein the roller 401 is initiated once rain, water, or wet weather is detected. A sensor suitable for use with such a device may include a moisture sensor, a humidity sensor, a barometric pressure sensor, a light sensor, or a temperature sensor. Similarly, the device may be connected to a database concerning weather predictions so the roller 401 may be initiated once rain is predicted. In the same or different embodiment, the roller 401 may also be initiated manually by the farmer, such as with a button, crank, or anything similar.

Roller 401 may further be any shape, size, or length, as long as the flexible optoelectronic device can be efficiently rolled up and stored away. The roller 401 and frame 402 are described herein in reference to the following dimensions shown in FIG. 4A-width 410, length 411, and height 412. Roller 401 may be the same width as the device or may have a different width. In an embodiment, roller 401 runs along the entirety of a side of the flexible OPV sheet. Roller 401 may be cylindrical, rectangular, triangular, or any shape suitable for storing the flexible OPV sheet in a rolled configuration. Furthermore, and in an embodiment, roller 401 may include a lip 406 on either end (along width 410) of the roller, for example to prevent the flexible sheet from sliding off the roller. In another embodiment, the width of roller 401 may be the same as a width and/or a height of frame 402. The roller may have a width between 1 m and 10 m, or between 1 m and 5 m, or between 1 m and 3 m, or about 2 m, or about 3 m, or about 4 m, or about 5 m. The roller may have a diameter, when in a rolled-up configuration, of 10 cm-1.5 m, 20 cm-80 cm, 30 cm-50 cm, or about 10 cm, about 20 cm, about 30 cm, about 40 cm, or about 50 cm. Roller 401 may be made of any material that is rigid enough to hold the weight of the optoelectronic device and withstand the harsh environment, such as, without limitation, metal, fiberglass, plastic etc.

Referring still to FIG. 4A, the disclosed optoelectronic system may further comprise a frame 402 configured to mount the roller 401 and the flexible OPV sheet 408 above the ground. Frame 402 may be configured to hold the flexible optoelectronic device 408 above crops. Frame 402 may mount the roller 401 and the device at a specific height above the ground. For example, frame 402 may hold the device and roller 401 at a height of between 10 cm and 10 m, or between 50 cm and 3 m, or between 1 m and 3 m, or at least 1 m, at least 2 m, at least 3 m, at least 4 m, or any other suitable height above the ground. In an embodiment, the height of frame 402 may be dependent on what type of crop or livestock may be occupying the space beneath the solar cells. Furthermore, the frame 402 may comprise a plurality of poles configured to support the roller 401 and the device. In one embodiment, the frame 402 may include four poles positioned at the corners of a rectangle or square, as shown in FIG. 4A. In another embodiment the frame 402 may comprise three poles, five poles, six poles, eight poles, or any other suitable number of poles or other support structures. Poles or support structures may in some embodiments be permanently or semi-permanently embedded into the ground. In some embodiments, the frame 402 or one or more support structures of the frame 402 may have an adjustable height, where the height and angle of the solar cells are adjustable, for example using a motor, hydraulic, or other linear actuator. Adjustments may be made for example in order to raise or lower the frame in response to an approaching person or machine, or in order to angle the ST PV to maximize exposure to sunlight.

Frame 402 may be made of any suitable material, and the same or different material may be used for the collapsible support structure 403. Materials suitable for use in roller 401, frame 402, and/or support structure 403 may include metals, such as aluminum or steel, polymer, composites, carbon fiber, any other material suitable for use in an outdoor environment.

As shown in FIG. 4A, the frame 402 may comprise a collapsible support structure 403 configured to aid the frame in holding up the roller 401 and the flexible OPV sheet 408. The collapsible support structure 403 may include any flexible, sturdy material that can withstand the weight of the device and distribute the weight among the frame 402. Further, the collapsible support structure 403 may be configured to position the flexible plastic substrate in an extended configuration over the frame from the roller 401. Additionally, the collapsible support structure 403 may be configured to position the flexible plastic substrate parallel or substantially parallel to the ground. In another embodiment, the collapsible support structure may be configured to position the flexible plastic substrate at an angle relative to the ground, for example at an angle 5 degrees, 10 degrees, 20 degrees, 30 degrees, 40 degrees, 50 degrees, 60 degrees, or any other suitable angle relative to the ground when deployed. In some embodiments, support structure 403 is collapsible so that it can be manipulated over the shape of frame 402. In an embodiment, collapsible support structure 403 may remain on top of frame 402, as shown in FIG. 4A, after the flexible OPV sheet has been retracted onto roller 401. In other embodiments, an actuator may be configured to retract the support structure 403 into a retracted position, for example beneath the roller 401, simultaneously or after the flexible OPV sheet is retracted onto roller 401. In some embodiments, the support structure 403 may be configured to be removed manually.

The collapsible support structure 403 may be configured as a plurality of straight elements joined together at a plurality of hinged intersection points, similar to a scissor-lift. The support structure 403 may alternatively be configured in any other retractable configuration.

Referring now to FIG. 4B, when retracted, the roller 401 may further be configured to rotate, for example with a hinge, into an orientation orthogonal to the ground as shown in FIG. 4B. The retracted configuration shown in FIG. 4B may be advantageous for allowing tall vehicles to pass under/through the structure, or in order to minimize the ground surface area shielded from rain.

An example OPV for use in agricultural settings is described in U.S. patent application Ser. No. 18/469,914, filed Sep. 19, 2023, which is hereby incorporated herein by reference in its entirety.

As always, the transparency spectrum of the cells can be adjusted during fabrication to optimize growth conditions for the specific crop being cultivated. Specifically the transparency of the cells can be tailored to provide maximum power while providing necessary solar nutrients to optimize crop growth beneath the panels. For example, crops such as kale, lettuce, cabbage, soy, corn, etc. require sunlight in the blue and red spectra for growth, but do not require sunlight in the green spectra for growth. This allows one to tailor the transparency of the cells in the red and blue while harvesting light in the green and the near infrared via the use of various mechanisms such as optical coatings.

In some embodiments, the photovoltaic cell is configured to absorb more energy in the wavelength range from 750 nm to 2.5 μm than in the range from 400 nm to 750 nm. In some embodiments, the photovoltaic cell is configured to absorb more energy in the wavelength range from 700 nm to 1.2 μm than in the range from 400 nm to 700 nm. In some embodiments, the photovoltaic cell is configured to absorb more energy in the wavelength range from 700 nm to 1.0 μm than in the range from 400 nm to 700 nm. In some embodiments, the photovoltaic cell is configured to absorb more energy in the wavelength range from 700 nm to 1.0 μm than in the range from 500 nm to 600 nm.

Further exemplary device designs, materials, and layer thicknesses can be found in U.S. patent application Ser. No. 17/036,472, “Near-Infrared Ternary Tandem Solar Cells”, filed Sep. 29, 2020, and incorporated herein by reference in its entirety.

In some embodiments, the photovoltaic cell is configured to absorb light in specific spectral ranges including in the near infra-red beyond 750 nm, such that the energy absorption by the cell in the NIR exceeds the energy absorption by the cell in the visible spectrum. In some embodiments, the photovoltaic cell is configured to absorb more energy in the wavelength range from 750 nm to 2.5 μm than in the range from 400 nm to 750 nm.

In some embodiments, the transparent organic photovoltaic cell comprises two or more sub-cells, wherein each of the two or more sub-cells are configured to absorb light of different spectral wavelength ranges such as those described herein. In some embodiments, each of the two or more sub-cells are further configured to transmit light of different spectral wavelength ranges such as those described herein. In some embodiments, the absorption and transmittance spectral ranges of each of the two or more sub-cells is tuned based on a plant's peak photosynthetic spectrum as described below for a corresponding plant receiving transmitted light from a corresponding sub-cell. In other words, each sub-cell is tuned for a specific plant type corresponding to (i.e. below) the sub-cell.

Further, the flexible optoelectronic device may comprise a motor configured to retract and deploy the flexible plastic substrate from a deployed configuration to a retracted configuration, and vice-versa. In one embodiment, the motor may be the same motor used for any other component of the optoelectronic system, such as water pumps or for an adjustable frame. The motor may be used by roller 401 to roll up the flexible device and also to move the roller 401 into the vertical retracted configuration described above. In an embodiment the motor may further be used to collapse the collapsible support structure.

Additionally, the flexible optoelectronic device may be at least semi-transparent to visible light. In an embodiment, the flexible optoelectronic device may be configured to be at least semi-transparent to light in a subset of the visible spectrum optimal for cultivation of a plant. In another embodiment, the flexible optoelectronic device may be configured to be almost fully transparent to light in a subset of the visible spectrum optimal for cultivation of a plant. In some embodiments, the flexible optoelectronic device may have less than 5% transparency for light having a wavelength greater than 600 nm, greater than 625 nm, greater than 650 nm, greater than 675 nm, greater than 700 nm, greater than 725 nm, greater than 750 nm, greater than 775 nm, or greater than 800 nm. The flexible optoelectronic device may also be receptive to light based on its specific color. For example, and without limitation, the flexible optoelectronic device may be at least 80%, at least 85%, at least 88%, at least 90%, at least 92%, at least 95%, at least 97%, or at least 99% transparent to red light (i.e. between 600 nm and 750 nm). In another embodiment, the flexible optoelectronic device may be at least 40%, at least 50%, between 40%-60% transparent, or about 50% transparent to blue light (i.e. between 450 nm and 495 nm). In another embodiment, but without limitation, the flexible optoelectronic device may be at most 50%, at most 45%, at most 40%, at least 5%, at least 10%, at least 15%, or 10%-30% transparent, or about 20% transparent, to green light (i.e. between 495 nm and 570 nm). These values (i.e. the transparency spectrum of the cells) can be adjusted during fabrication to optimize growth conditions for the specific crop being cultivated.

Now referring to FIG. 5, another exemplary image of the optoelectronic system is shown. The semi-transparent OPV module is placed on top of the frame, or module support, including a collapsible structure. Also included is a roller or roll up the ST-OPV for storage.

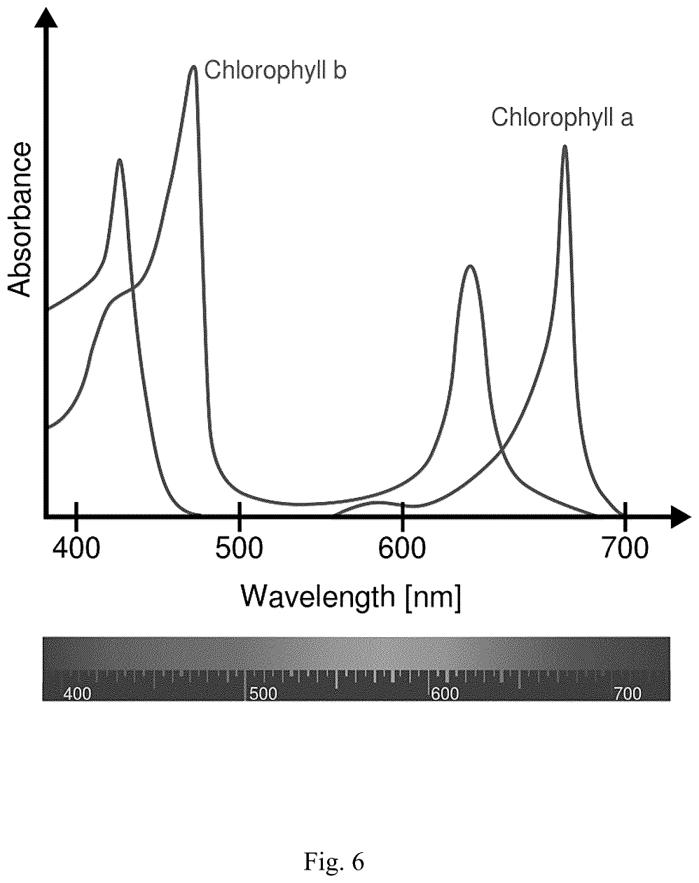

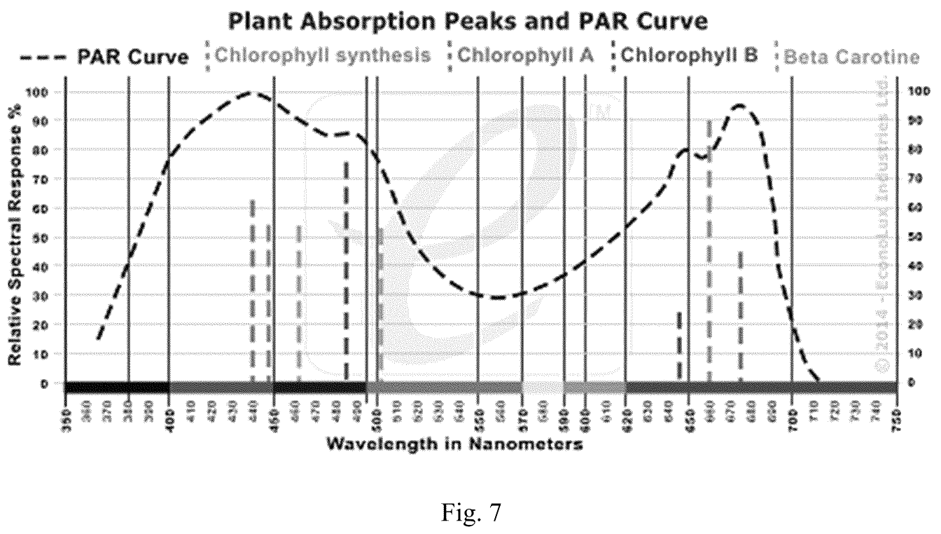

Example photosynthesis and PAR spectra are shown in FIGS. 6 and 7, respectively. As shown in FIG. 6, there are two forms of Chlorophyll called Chlorophyll A and Chlorophyll B. Each has absorption peaks in both the red and blue spectrums, and both reflect yellow and green (giving plants their green color), so while the green/yellow bands can be absorbed by other pigments like the Carotenoids, over 50% of this spectrum range is reflected away and/or poorly utilized. As shown in FIG. 7, absorption right around the green/yellow boundary is under 50% and as low as 30% and from 620 nm (orange/red boundary) to 520 nm (Blue/Green boundary). There are other pigments besides Chlorophyll that can absorb and utilize this spectrum range, but they are far less efficient and typically located deeper in the leaf because they get most of their photons from light that is reflected off the leaves and bounces deeper into the canopy and is absorbed through the bottom of the leaves.

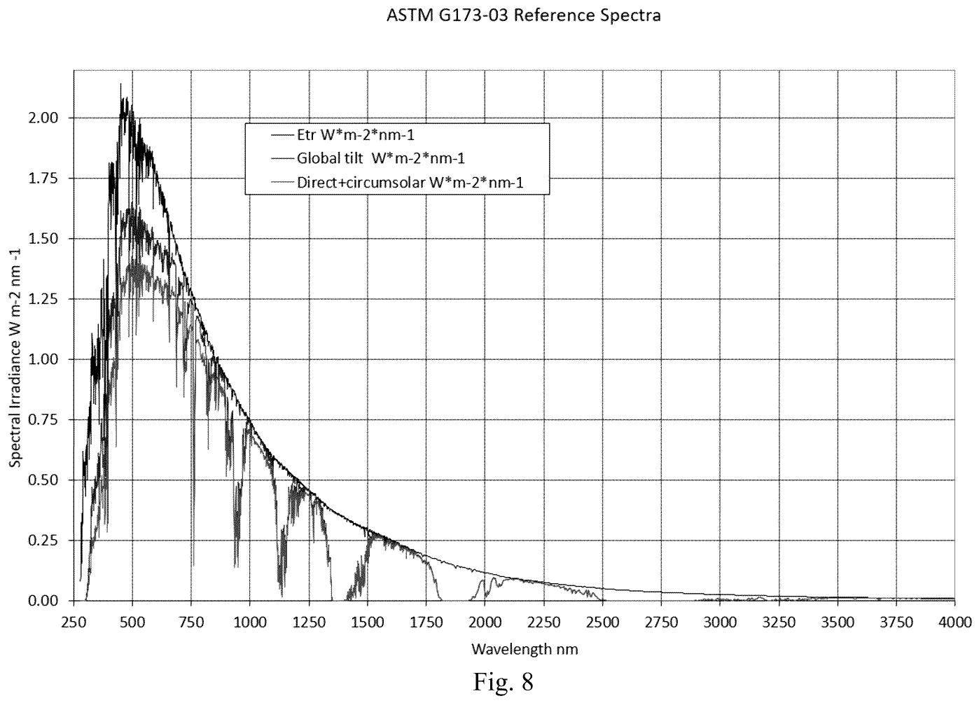

FIG. 8 shows exemplary solar spectra. Based on the spectra one can calculate the energy of the solar spectrum for specific energy ranges as shown in Table 1:

TABLE 1

| Wavelength (nm) | W/m² |
|---|---|
| 280-400 | 30.7 |
| 400-500 | 115.4 |
| 500-600 | 133.8 |
| 600-700 | 125.8 |
| 700-800 | 103.4 |
| 800-1,000 | 140.5 |
| 1,000-1,500 | 150.2 |
| 1,500-1,700 | 46.3 |

If for example one assumes plants absorb visible light in the blue and red color ranges and light in the 500-600 nm range is absorbed by the solar cell then the energy absorbed by the solar cell for visible light is approximately 134 W/m². Meanwhile, energy in the NIR (700-1000 nm) available for absorption is approximately 243.9 W/m². Thus, assuming plants absorb 50% of energy from 400-500 nm and 600-700 nm, the visible energy that can be absorbed by the solar cell is approximately 254.4 W/m²=(133.8±0.5*(115.4±125.8)).

Plants utilize different light spectrums as follows:

Ultraviolet Light (10 nm-400 nm)

Though overexposure to UV light is dangerous for the flora, small amounts of near-UV light can have beneficial effects. In many cases, UV light is a very important contributor to plant colors, tastes and aromas. This is an indication of near-UV light effect on metabolic processes. Studies show that 385 nm UV light promotes the accumulation of phenolic compounds, enhances antioxidant activity of plant extracts, but does not have any significant effect on growth processes. UVB has also been demonstrated to elevate THC levels in Cannabis.

Blue Light (430 nm-450 nm)

This range of spectrum enables cryptochromes and phototropins to mediate plant responses such as phototropic curvature, inhibition of elongation growth, chloroplast movement, stomatal opening and seedling growth regulation. It affects chlorophyll formation, photosynthesis processes, and through the cryptochrome and phytochrome system, raises the photomorphogenetic response.

In more practical terms, these wavelengths encourage vegetative growth and are essential in lighting for seedlings and young plants during the vegetative stage of their growth cycle, especially when “stretching” must be reduced or eliminated. It also stimulates the production of secondary pigments which can enhance colors and is known to also stimulate Terpene (i.e. fragrance) production.

Green Light (500 nm-550 nm)

Most green light is reflected off the plant and plays a much smaller role in plant growth. However, there are some important aspects of light in this range so a certain amount of light in this spectrum range is beneficial. Green light is sometimes used as a tool for eliciting specific plant responses such as stomatal control, phototropism, photomorphogenic growth and environmental signaling. When combined with blue, red and far-red wavelengths, green light completes a comprehensive spectral treatment for understanding plant physiological activity. The function of green light is less well understood than the other spectrums, and there are only certain species of plants that require green light for normal growth. Its effects appear to be very strain specific.

The pigments that can absorb green are found deeper in the leaf structure so it is thought that because green light reflects off of the Chlorophyll in leaf surfaces and thus is reflected deeper into the shaded areas of the canopy than Red and Blue which are readily absorbed, that green may actually be mostly absorbed through the undersides of the leaves as it bounces around in the shaded depths of the canopy.

Red Light (640 nm-680 nm)

Red light affects phytochrome reversibility and is the most important for flowering and fruiting regulation. These wavelengths encourage stem growth, flowering and fruit production, and chlorophyll production.

The 660 nm wavelength has a very strong photosynthetic action and also exhibits the highest action on red-absorbing phytochrome regulated germination, flowering and other processes. Most effective for light cycle extension or night interruption to induce flowering of long-day plants or to prevent flowering of short-day plants.

### Far Red (730 nm)

Although the 730 nm wavelength is outside the photosynthetically active range, it has the strongest action on the far-red absorbing form of phytochrome, converting it back to the red-absorbing form. It becomes necessary for plants requiring relatively low values of the phytochrome photoequilibrium to flower. Can be used at the end of each light cycle to promote flowering in short-day plants such as Cannabis.

Also, a higher ratio of far-red to red than found in sunlight can trigger the shade stretch response—where a plant when sensing it is shaded based on an elevated ratio of far-red to red-will stretch to try to elevate its canopy above its competitors. This is why too much far-red is not advised if compact plants are desired, or in general.

By utilizing the knowledge of what light wavelength ranges plants need most, the solar cell can be configured to allow light in these ranges to pass, and light outside these ranges to be reflected back into the solar cell for electricity generation.

In some embodiments, a semi-transparent organic solar cell comprises a combination of donor and acceptor molecules that absorb light in specific spectral ranges and is designed to be placed over crops and plants such that light not absorbed by the solar cells is transmitted to the plants.

In some embodiments, since some plants absorb specific wavelengths of light characterized by absorption peaks, the solar cell is configured such that the solar cell transmission is at least 30%, 50% or 70% higher at these absorption peaks than at a wavelength 100 nm on either side of the peaks.

In some embodiments, since some plants absorb specific wavelengths of light characterized by at least 2 absorption peaks, the solar cell is configured such that the solar cell transmission is at least 30%, 50% or 70% higher at these absorption peaks than at a wavelength in between the 2 peaks.

In some embodiments, over 50% of light from the solar cells is transmitted within +/−50 nm of the dominant absorption peak in the plants. In some embodiments, over 30% of light from the solar cells is transmitted within +/−50 nm of the dominant absorption peak in the plants.

In some embodiments, over 50% of light in the spectral range from 400 nm-480 nm is transmitted, while light outside of this band is reflected back into the cell. In some embodiments, over 50% of light in the spectral range from 600 nm-700 nm is transmitted, while light outside of this band is reflected back into the cell. In some embodiments, over 50% of light in the combined spectral range of 400 nm-480 nm and 600 nm-700 nm is transmitted, while light outside of this combined band is reflected back into the cell.

In some embodiments, the optical coatings used to transmit and reflect these spectral bands are designed using the transfer matrix method in combination with a genetic algorithm for optimization. In some embodiments, the optical coatings used to transmit and reflect these spectral bands comprise aperiodic layer thicknesses. An example genetic algorithm and aperiodic layer thicknesses are described in U.S. patent application Ser. No. 17/932,577, filed Sep. 15, 2022, and Hafiz K. M. Sheriff et al., Appl. Phys. Lett. 118, 033302 (2021), each of which is hereby incorporated herein by reference in its entirety.

Combination with Other Materials

The materials described herein as useful for a particular layer in an organic optoelectronic device may be used in combination with a wide variety of other materials present in the device. The materials described or referred to below are non-limiting examples of materials that may be useful in combination with the compounds disclosed herein, and one of skill in the art can readily consult the literature to identify other materials that may be useful in combination.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. The hole-transporting layer can be doped by p-type conductivity dopants and n-type conductivity dopants are used in the electron-transporting layer.

### REFERENCES

The following publications are incorporated by reference herein in their entireties:
U.S. patent application Ser. No. 17/932,577, “High Efficiency, Color Neutral, Semi-transparent Organic Photovoltaics for Energy Harvesting Windows”, filed Sep. 15, 2022.
U.S. Patent Application No. 63/408,745, “Organic Optoelectronic Device and Method”, filed Sep. 21, 2022.
U.S. patent application Ser. No. 17/036,472, “Near-Infrared Ternary Tandem Solar Cells”, filed Sep. 29, 2020.
Suen, Chyi-Shan, and Xi Chu. “Multilayer thin film barrier for protection of flex-electronics.” Solid State Technology, vol. 51, no. 3, March 2008, pp. 36±
S. R. Forrest, Organic Electronics: Foundations to Applications. Oxford, UK: Oxford University Press, 2020.
Hafiz K. M. Sheriff Jr., Yongxi Li, Boning Qu, and Stephen R. Forrest, Appl. Phys. Lett. 118, 033302 (2021)

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention. The appended claims are intended to be construed to include all such embodiments and equivalent variations.

1. A transparent organic photovoltaic cell, comprising:
first and second electrodes; and
an active layer between the electrodes, comprising a combination of donor and acceptor molecules which are configured absorb light in one or more sub-spectral ranges within a total spectral range of 400 nm to 2000 nm.

2. The transparent organic photovoltaic cell of claim 1, wherein the photovoltaic cell is configured to absorb more energy in the wavelength range from 750 nm to 2.0 μm than in the range from 400 nm to 750 nm.

3. The transparent organic photovoltaic cell of claim 1, wherein the photovoltaic cell is configured to absorb more energy in the wavelength range from 700 nm to 1.2 μm than in the range from 400 nm to 700 nm.

4. (canceled)

5. The transparent organic photovoltaic cell of claim 1, wherein the photovoltaic cell is configured such that the photovoltaic cell transmission is at least 30%, higher for a wavelength associated with an absorption peak of the plant than at wavelengths 100 nm on either side of the plant absorption peak.

6. The transparent organic photovoltaic cell of claim 1, wherein the photovoltaic cell is configured such that the photovoltaic cell transmission is at least 30%, higher at two or more wavelengths associated with two or more absorption peaks of the plant than at wavelengths 100 nm on either side of the two or more plant absorption peaks.

7. The transparent organic photovoltaic cell of claim 1, wherein the photovoltaic cell is configured such that the photovoltaic cell transmission is at least 30%, higher at a wavelength between two or more absorption peaks of the plant.

8. (canceled)

9. The transparent organic photovoltaic cell of claim 1, wherein the photovoltaic cell is configured to transmit over 30% of light within +/−50 nm of a dominant plant absorption peak.

10. The transparent organic photovoltaic cell of claim 1, wherein the photovoltaic cell is configured such that over 50% of light in a spectral range from 400 nm to 480 nm is transmitted, while at least 30% of light outside of the spectral range is reflected back into the cell.

11. The transparent organic photovoltaic cell of claim 1, wherein the photovoltaic cell is configured such that over 50% of light in a spectral range from 600 nm to 700 nm is transmitted, while at least 30% of light outside of the spectral range is reflected back into the cell.

12. (canceled)

13. The transparent organic photovoltaic cell of claim 1, further comprising a stack comprising a plurality of optical coating layers, wherein a thickness of at least one of the optical coating layers is different than a thickness of at least one of the other optical coating layers.

14. The transparent organic photovoltaic cell of claim 1, wherein the photovoltaic cell is configured to absorb more energy in the wavelength range from 700 nm to 1.0 μm than in the range from 500 nm to 600 nm.

15. The transparent organic photovoltaic cell of claim 1, wherein the organic photovoltaic cell is configured to transmit at least 30% of light in the wavelength range from 400 nm to 750 nm.

16. The transparent organic photovoltaic cell of claim 1, wherein an absorption spectrum of the organic photovoltaic cell has a first absorption peak in the range of 660 nm+/−50 nm and a second absorption peak in the range of 450 nm+/−50 nm.

17-18. (canceled)

19. The transparent organic photovoltaic cell of claim 1, further comprising two or more sub-cells, wherein each of the two or more sub-cells are configured to absorb and transmit light of different spectral wavelength ranges.

20. The transparent organic photovoltaic cell of claim 19, wherein absorption and transmittance characteristics of each of the two or more sub-cells is tuned based on a plant's peak photosynthetic spectrum for the plant receiving transmitted light from the corresponding sub-cell.

21. (canceled)

22. A consumer product comprising the transparent organic photovoltaic cell of claim 1, the product selected from a display screen, a lighting device, a discrete light source device, a lighting panel, a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign, an electronic component module, a solar cell, a light weight solar cell, a flexible solar cell, a solar cell integrated with thin film electronics, a thin film power supply, a solar farm, a radio receive/transmitter, an audio producing device, a computing device, an IT device, a shelf label, a window, wall, or roof.

23. A solar farm comprising at least one of the transparent organic photovoltaic cell of claim 1, configured to generate electricity while providing light for plant growth below the at least one photovoltaic cell.

24. A transparent organic photovoltaic cell production method, comprising:
depositing a first electrode onto a substrate;
depositing an active layer above the first electrode, the active layer comprising a plurality of sub-layers comprising a combination of donor and acceptor molecules which are configured absorb light in one or more sub-spectral ranges within a total spectral range of 400 nm to 2000 nm; and
depositing a second electrode above the active layer;
wherein the photovoltaic cell is configured to be placed in optical communication with a plant such that at least a portion of light not absorbed by the photovoltaic cell is transmitted to the plant.

25. The method of claim 24, further comprising the step of selecting thicknesses and materials of the plurality of sub-layers of the active layer using a transfer matrix method in combination with a genetic algorithm for optimization of light absorption for power generation and light transmission for growth of the plant in optical communication with the photovoltaic cell.

26. A transparent organic photovoltaic cell, comprising:
first and second electrodes; and
an active layer positioned between the electrodes, comprising a combination of donor and acceptor molecules configured to absorb light in specific spectral ranges including in the range of 750 nm to 990 nm;
wherein the photovoltaic cell is configured to be placed in optical communication with a plant such that at least a portion of light not absorbed by the photovoltaic cell is transmitted to the plant, such that the energy absorption by the cell in the range exceeds the energy absorption by the cell in a range from 380 nm to 700 nm.
